(19) United States
(12) Patent Application Publication
(10) Pub. No.: US 2025/0305135 A1
(43) Pub. Date: Oct. 2, 2025

(54) SEMICONDUCTOR DEVICE WITH SPACER LAYERS FORMED BY PRECURSOR COMPOUND, FILM DEPOSITED WITH THE SAME, AND METHOD OF MANUFACTURING THE FILM

(71) Applicant: Taiwan Semiconductor Manufacturing Company, Ltd., Hsinchu (TW)

(72) Inventors: Hung-Yu YEN, Hsinchu (TW); Yu-Yun PENG, Hsinchu (TW); Keng-Chu LIN, Hsinchu (TW)

(73) Assignee: Taiwan Semiconductor Manufacturing Company, Ltd., Hsinchu (TW)

(21) Appl. No.: 18/618,427

(22) Filed: Mar. 27, 2024

(51) Int. Cl. C23C 16/455; H01L 21/02; H01L 29/66

(52) U.S. Cl. CPC C23C 16/4554; H01L 21/02208; H01L 21/0228; H10D 64/021

(57) ABSTRACT

The present disclosure is related to a semiconductor device with spacer layers formed by a precursor compound, a film deposited with the same and a method of manufacturing the film, which uses an atomic layer deposition (ALD) method to achieve a film deposition. The precursor compound contains a cyclic main chain of Si—C—Si bonds, and the cyclic main chains are ring-opened by UV light to form a plurality of non-cyclic monomers, and the non-cyclic monomers are polymerized to form a linear polymer.

### BACKGROUND

As a method of depositing a dielectric film on a substrate, chemical vapor deposition (CVD) and atomic layer deposition (ALD) are typically known. Technicians often use plasma-enhanced CVD (PE-CVD) and plasma-enhanced ALD (PE-ALD) to form dielectric films. PE-ALD is a dielectric film deposition technology that utilizes precursor chemical adsorption. Compared with PE-CVD, it can improve the step coverage of films deposited on the recessed pattern of the substrate. However, when a dielectric film other than an SiO film is deposited on a recessed pattern through PE-ALD, in which a nitration or carbon substitution reaction is performed in a plasma atmosphere, the thickness of the film deposited on the sidewall is sometimes small relative to the thickness of the film deposited on the top surface. The problem may be caused by ion collisions on the sidewalls interfering with the reaction rate compared to ion collisions on the top or bottom surfaces. In particular, compared with oxidation, nitrification has a low sidewall reaction rate, leading to problems such as thin films deposited on the sidewalls and deterioration of the films deposited on the sidewalls. Step coverage and thickness of depositing film are affected by the reactivity of the precursor with the reactive gas. It is necessary to increase the reactivity within the trench or recess not only in PE-ALD but also in other cyclic deposition methods.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are schematic diagrams of a patterned trench formed with a patterned dielectric layer according to an embodiment of the present disclosure.

FIGS. 2A to 2B respectively illustrate a flow chart of a method of manufacturing a film according to an embodiment of the present disclosure.

FIGS. 3A to 3C are schematic diagrams showing the conversion of a precursor compound with a cyclic main chain into a polymer with a non-cyclic structure.

FIGS. 3D to 3E are schematic diagrams of multiple film layers bonded as linear polymers.

FIG. 4 is a schematic diagram of a gate structure according to an embodiment of the present disclosure.

FIG. 5 is a schematic diagram of a gate structure according to another embodiment of the present disclosure.

FIGS. 6A to 6B are schematic diagrams of a method of manufacturing a semiconductor device according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure, “gas” may include vaporized solids and/or liquids and may consist of a single gas or a mixture of gases. In the present disclosure, “precursor having Si—C—Si bonds” may refer to a film characterized by Si—C—Si bonds, a precursor compound consisting of silylcyclopentane containing Si—C—Si bonds, and/or a monomer consisting essentially of silylcyclopentane containing Si—C—Si bonds, chloromethyl groups and silyl groups.

In this disclosure, when the precursor is vaporized and carried by the rare gas, the precursor may include the rare gas as a carrier gas, and the flow of the precursor is controlled by the inflow pressure (the pressure of the gas flowing into the reactor). Furthermore, precursors are materials from which a film layer is derived and provides the main elements of the film layer. The precursor contains silicon and may be mixed with other elements (e.g., carbon, halogens) to form a cyclic main chain with Si—C—Si bonds. The precursors can be attached to any surface or any film layer through ALD or other cyclic deposition, and the pulsed UV light in the excited state can interact with the precursors chemically adsorbed on the substrate to break the Si—C bond.

In this disclosure, when two or more steps can be performed continuously, “continuous” means not breaking the vacuum, not interrupting the timeline, not changing the processing conditions, immediately following, as the next step, or not existing discrete physical or chemical processes. In some embodiments, a “film” is a layer that is composed of multiple monolayers (composed of the same monolayer or different monolayers) and extends continuously in a direction perpendicular to the thickness direction without substantially holes to cover the entire target or associated surfaces, or simply a layer consisting of multiple monolayers. The film or layer may consist of a discrete single film or layers with common properties.

In the present disclosure, it is not necessary to use a reactant gas for oxidizing the precursor. Furthermore, no reactant gases are used, but only inert gases (as carrier gas and/or diluent gas). The term “precursor” generally refers to a compound that participates in a chemical reaction to produce another compound, specifically a compound that constitutes the film matrix or the main structure of the film, while the term “reactant” refers to compounds other than the precursor. It is a reaction of an activated precursor, a modified precursor, or a catalytic precursor when UV power is applied, the UV power can provide energy to break the cycle-type bonding and become a non-cyclic structure. The term “inert gas” refers to a gas that excites the precursor when UV power is applied but, unlike the reactants, does not become part of the film matrix to a significant extent.

For example, traditional oxidation treatment is a thermal oxidation treatment or a plasma oxidation treatment. In the thermal oxidation process, oxygen-containing processing gas, such as oxygen (O₂), ozone gas (O₃), nitrous oxide (N₂O), nitric oxide (NO), or a combination thereof, may flow through the processing chamber. The oxygen-containing processing gas may flow into the processing chamber continuously, or may flow into the processing chamber until a desired pressure is reached and stopped, and then maintained at that pressure during the oxidation process. The thermal oxidation treatment can be carried out at temperatures greater than 300° C.

Traditional silicon oxide films are converted from silicon-based dielectrics that include high concentrations of nitrogen and/or hydrogen deposited through an ALD process. The silicon-based dielectrics can react to form Si—O—Si bonds or weak Si—C bonds through annealing. However, the traditional oxidation treatment has limited ability to fill gaps with high aspect ratios and easily forms voids or seams in the gaps, causing poor reliability or quality.

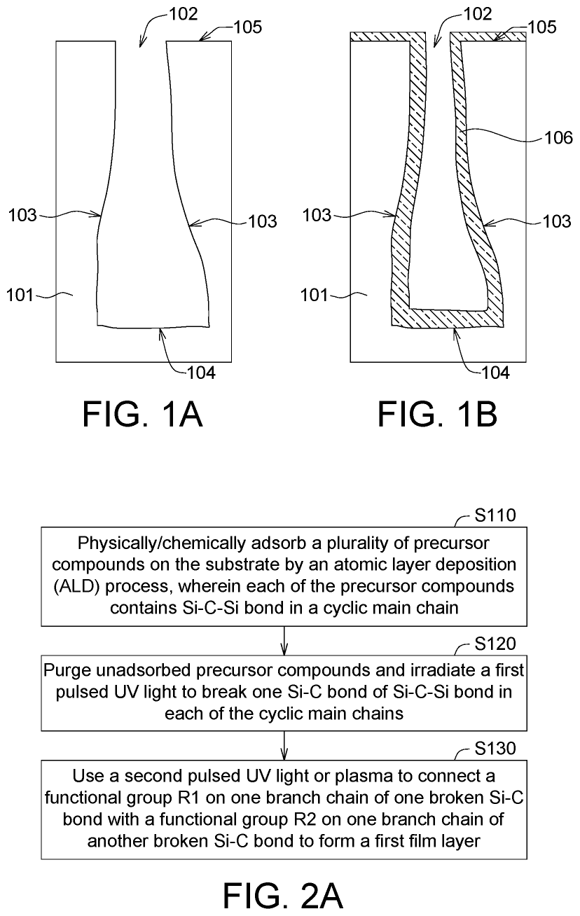

Referring to FIGS. 1A and 1B, the semiconductor substrate 101 is etched to form a patterned trench 102, and atomic layer deposition is performed on the patterned trench 102 to form a patterned dielectric layer 105 in the patterned trench 102. In some embodiments, each patterned trench 102 includes sidewalls 103 and a bottom surface 104. In some embodiments, the patterned dielectric layer 105 has sidewall coverage typically exceeding 85%, which is defined as the ratio of the thickness of the film deposited on the sidewalls to the thickness of the film deposited on the top surface (e.g., the patterned trench 102 has an opening of 30 to 100 nm and a depth of 200 to 400 nm). In some embodiments, sidewall coverage may be greater than 80%, 90% or higher, or 95% or higher. In some embodiments, the sidewall coverage is substantially similar with the bottom surface coverage (e.g., the difference is less than 5, 3, or 1 percentage), which is defined as the ratio of the thickness of the film deposited on the bottom surface to the thickness of the film deposited on the top surface. The bottom surface coverage can be at least about 85%, 90%, or 95%. In traditional methods, sidewall coverage is typically lower than bottom surface coverage about 10 to 20 percentages.

Before performing ALD or other cyclic deposition, a pretreatment process (such as a pre-soak process) is performed on the substrate. For example, the processing gas and the rare gas are supplied without supplying the precursor gas and the reaction gas. Continuously supplying a processing gas (such as oxygen or ammonia (NH₃)), and applying radio frequency power to excite the processing gas and the rare gas to treat the surface of the substrate 101, thereby selectively affecting the chemical adsorption of the precursors on the top and bottom surfaces relative to the sidewalls, and make the degree of chemical adsorption on the sidewalls roughly match the degree of chemical adsorption on the top and bottom surfaces. After that, a purge step is performed in which only the rare gas is supplied as the purge gas, and other gases are not supplied, and RF power is not applied. In some embodiments, an inert gas may be supplied as the purge gas. Alternatively, the rare gas may be supplied in pulses together with the processing gas, rather than continuously supplying the rare gas throughout the process.

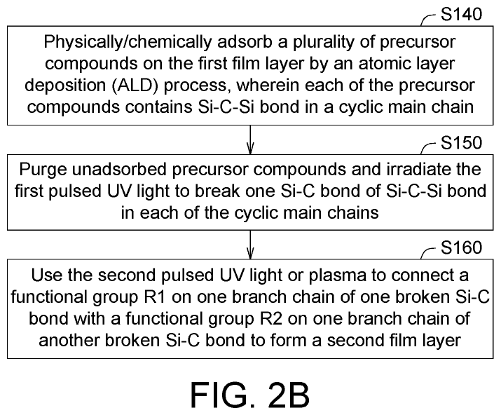

Referring to FIG. 2A, a flow chart of a method of manufacturing a film according to an embodiment of the present disclosure is shown, which includes the following steps: Step 110, a plurality of precursor compounds is physically/chemically adsorbed on a substrate by an atomic layer deposition (ALD), each of the precursor compounds contains a Si—C—Si bond in a cyclic main chain; step 120, a gas is used to purge unadsorbed precursor compounds and a first pulsed UV light irradiates on the precursor compounds to break one Si—C bond of the Si—C—Si bond in the cyclic main chain; step 130, a second pulsed UV light or plasma is used to connect a functional group R1 on one branch chain of one broken Si—C bond with a functional group R2 on one branch chain of another broken Si—C bond to form a first film layer.

In some embodiments, the functional group R1 is cross-linked with the functional group R2 to produce another functional group R3 and release a by-product. For example, the functional group R1 is SiH₃, the functional group R2 is CH₂Cl, the functional group R3 is SiCH₄, and the released by-product is HCl. The functional group R3 also contains a Si—C bond, and the functional group R3 is connected with two precursor compounds to form a strong Si—C—Si bond to increase the bonding force.

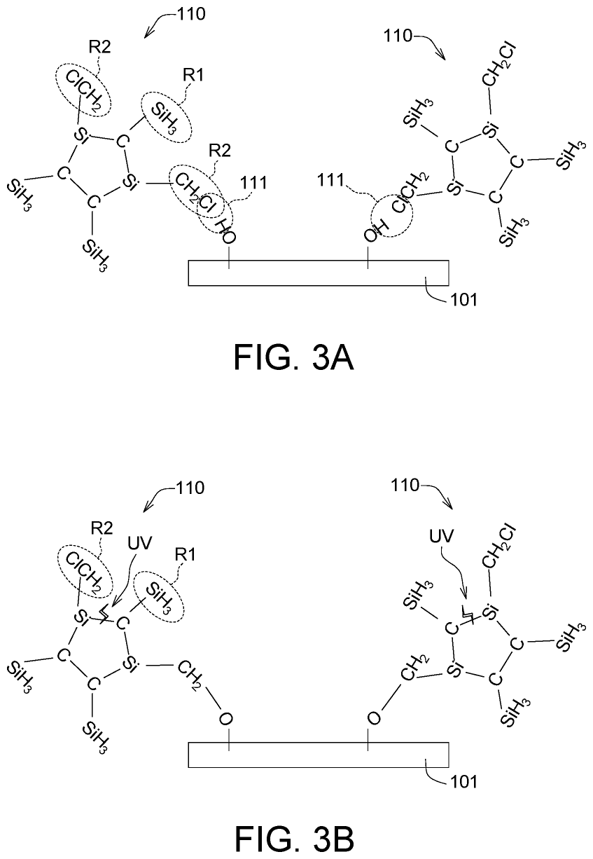

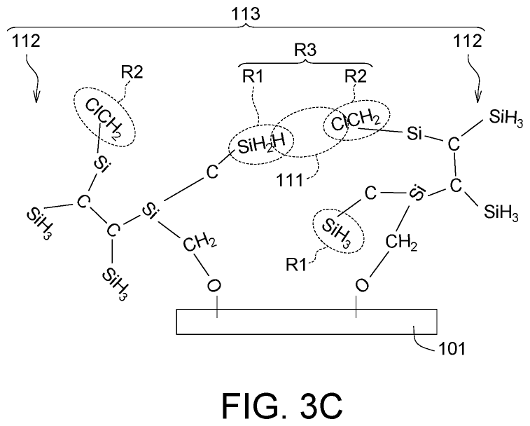

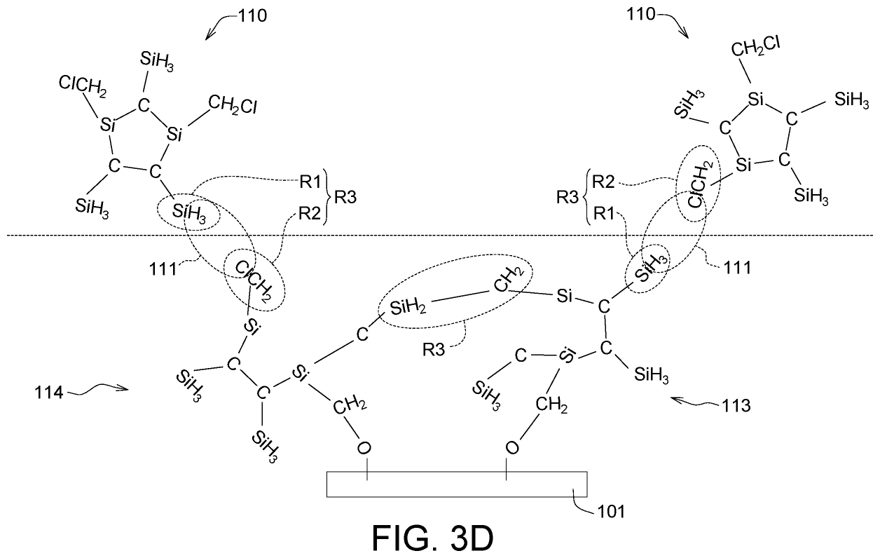

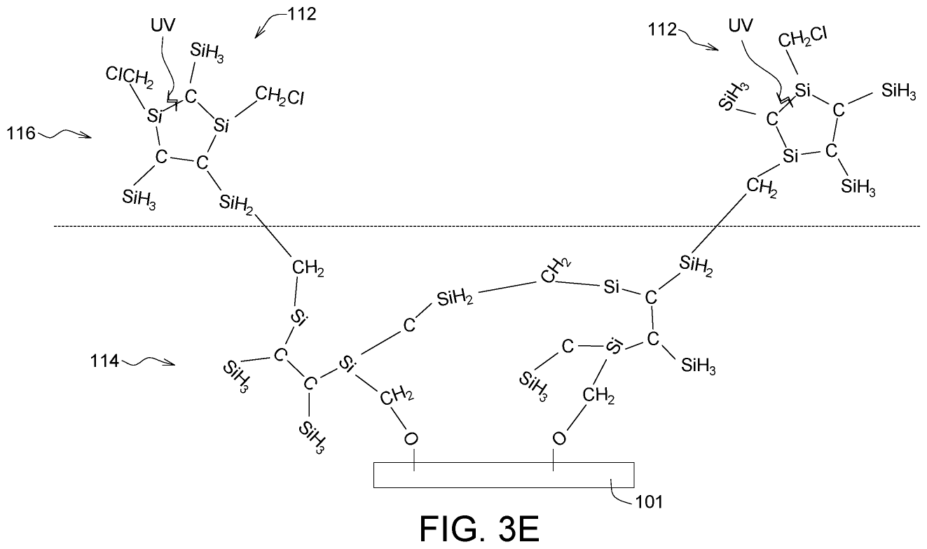

As shown in FIG. 3A, hydroxide ions may be formed on the pretreated substrate 101 (such as a single crystalline semiconductor material such as, but not limited to silicon (Si) or germanium (Ge), silicon germanium (SiGe), or a silicon-on-insulator substrate). For example, a pretreatment process (such as a pre-soak process) is performed on the substrate 101. Continuously supplying a processing gas (such as oxygen or ammonia (NH₃)), and applying radio frequency power to excite the processing gas and the rare gas to treat the surface of the substrate 101, thereby selectively affecting the chemical adsorption of the precursors on the top and bottom surfaces relative to the sidewalls, and the precursor compounds 110 can bond with the hydroxide ions through the functional group R2, adsorbed on the substrate 101 and produce by-products 111 (e.g. HCl). The precursor compounds 110 contain a cyclic main chain of Si—C—Si bond, a silyl group is on one branch of the Si—C—Si bond, and a chloromethyl group is on the other branch of the Si—C—Si bond. As shown in FIG. 3B, the above-mentioned precursor compounds 110 are ring-opened by UV light, and the ring-opened compound is still a monomer. Although the Si—C bond is broken, the precursor compounds 110 still have other parts connected together to become a non-cyclic monomer 112. As shown in FIG. 3C, two non-cyclic monomers 112 are polymerized to form a linear polymer 113. The reaction in which the cyclic precursor compounds 110 are ring-opened to convert into a linear polymer 113 through polymerization is called ring-opening polymerization.

In some embodiments, the precursor compounds 110 are represented by the following chemical formula 1.

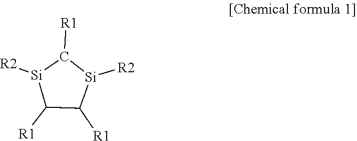

In chemical formula 1, R1 is a functional group containing silicon, and R2 is a functional group containing carbon. The functional group R1 is, for example, a silyl group (SiH₃), and the functional group R2 is, for example, a chloromethyl group (CH₂Cl). When one Si—C bond of the Si—C—Si bond is broken, the cyclic precursor compound 110 becomes a non-cyclic monomer 112 through ring opening, which is represented by the following chemical formula 2.

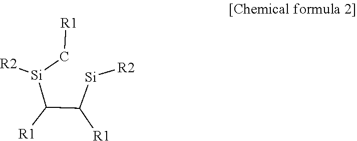

Next, as shown in FIG. 3C, two non-cyclic monomers 112 are converted into a linear polymer 113, in which the functional group R1 (i.e., silyl group) on the branch of non-cyclic monomer 112 has the opportunity to bond with the functional group R2 (i.e., chloromethyl group) on the branch of another non-cyclic monomer 112, becoming another functional group R3 (i.e., SiCH₄) and releasing by-products 111 (e.g. HCl). In other words, R1+R2→R3+by-product. The linear polymer 113 after the ring-opening polymerization is represented by the following chemical formula 3.

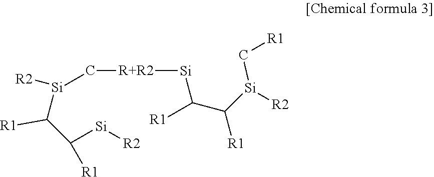

In the same manner, the ring-opening polymerization can convert three or more non-cyclic monomers 112 into a linear polymer 113, in which the functional group R1 on the branch of the first non-cyclic monomer 112 has the opportunity to bond with the functional group R2 on the branch of the second non-cyclic monomer 112 to form a functional group R3. The functional group R1 on the branch of the second non-cyclic monomer 112 has the opportunity to bond with the functional group R2 on the branch of the third non-cyclic monomer 112 to form another functional group R3. By analogy, after continuous ring-opening polymerization of the non-cyclic monomers 112, a first film layer 114 can be formed on the substrate 101. The first film layer 114 is represented by the following chemical formula 4.

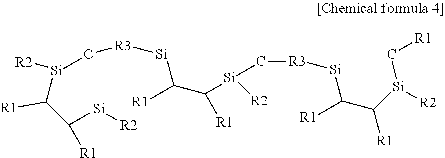

In view of chemical formula 4, it can be seen that the functional group R3 in the first film layer 114 also contains a Si—C bond connected to the continuous Si—C—Si bonds to form a linear polymer 113 with strong and continuous bonding force, thereby increasing the bonding force of the first film layer 114.

In some embodiments, the deposition temperature of the substrate 101 may be 50° C. to 400° C., but is not limited thereto. Another important feature of atomic layer deposition is that high-quality films can be obtained at lower growth temperatures. The adsorbed precursor compounds can react completely, so even at lower growth temperatures, the level of impurities contained is lower than that of chemical vapor deposition. The atomic layer deposition method of the present disclosure requires adsorption of precursor compounds and thermal activation of surface reactions on the substrate 101, so the substrate 101 is usually required to be heated. For example, the temperature of the substrate 101 may be 50° C. to 400° C., such as 50° C. to 100° C., 50° C. to 150° C., 50° C. to 200° C., 50° C. to 250° C., 50° C. to 300° C., 50° C. to 350° C., 300° C. to 400° C., or 350° C. to 400° C., but the present disclosure is not limited thereto.

In some embodiments, the injection time of the precursor compounds 110 may be from 1 second to 20 seconds, but is not limited thereto.

Referring to FIG. 2B, a flow chart of a method of manufacturing a film according to an embodiment of the present disclosure is shown. After completing the method of manufacturing the first film layer 114 in FIG. 2A, the manufacturing method further includes the following steps: Step 140, a plurality of precursor compounds is physically/chemically adsorbed on the first film layer 114 by an atomic layer deposition (ALD), each of the precursor compounds contains a Si—C—Si bond in a cyclic main chain, which have the same composition as the precursor compounds in step S110; Step 150, a gas is used to purge unadsorbed precursor compounds and the first pulsed UV light is irradiated to break one Si—C bond of the Si—C—Si bond in the cyclic main chain; Step 160, the second pulsed UV light or plasma is used to connect a functional group R1 on one branch chain of one broken Si—C bond with a functional group R2 on one branch chain of another broken Si—C bond to form a second film layer.

The above-mentioned steps 150 and 160 also adopt ring-opening polymerization to convert two or more non-cyclic monomers 112 into linear polymers, in which the functional group R1 (i.e., silyl group) on the branch of non-cyclic monomer 112 has the opportunity to bond with the functional group R2 (i.e., chloromethyl group) on the branch of another non-cyclic monomer 112, becoming another functional group R3 (i.e., SiCH₄) and releasing by-products 111 (e.g. HCl). In other words, R1+R2-R3+by-product. The non-cyclic monomers 112 form a linear polymer 113 on the first film layer 114 after a ring-opening polymerization to be the second film layer 116, which is represented by chemical formula 4 and will not be described again here.

As shown in the FIG. 3D, the precursor compounds 110 are formed on the first film layer 114, and a functional group R1 (i.e., silyl group) on the branch of the linear polymer 113 of the first film layer 114 has the opportunity to bond with a functional group R2 (i.e., chloromethyl group) on the branch of a cyclic monomer in the precursor compounds 110 to form another functional group R3 (i.e., SiCH₄) and releases by-products 111 (e.g. HCl). Since the functional group R3 also contains a Si—C bond and is connected to the Si—C—Si bonds between the first film layer 114 and the precursor compounds 110 in the upper and lower layers respectively, a film with strong and continuous bonding force is formed, thereby increasing the bonding force between the first film layer 114 and the precursor compounds 110.

Next, as shown in FIG. 3E, the cyclic main chains in the precursor compounds 110 are ring-opened to form non-cyclic monomers 112. The above-mentioned precursor compounds 110 are ring-opened by UV light, and the ring-opened compound is still a monomer. Although the Si—C bond is broken, the precursor compounds 110 still have other parts connected together to become a non-cyclic monomer 112. After that, two or more non-cyclic monomers 112 are converted into a linear polymer 113 after polymerization reaction, which is the same as that in FIG. 3C above and will not be described again here. The second film layer 116 has substantially the same composition and structure as the first film layer 114 and is therefore not shown in the drawings.

After the method of manufacturing the second film layer 116 in FIG. 2B, multiple precursor depositions and ring-opening polymerizations are subsequently performed to form a third film layer on the second film layer, to form a four film layer on the third film layer, . . . , and to form a Nₜₕ film layer on the N−1ₜₕ film layer until a predetermined film thickness is deposited, where N is a positive integer greater than 2, and N is, for example, between 10 and 100. The deposited film thickness is, for example, about 5 nm to about 200 nm.

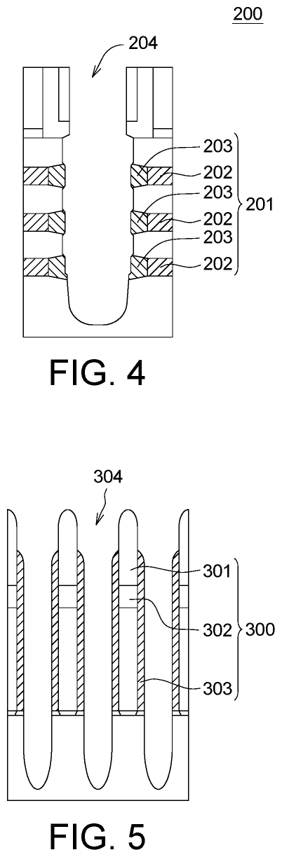

Referring to FIG. 4, a schematic diagram of a gate structure 200 according to an embodiment of the present disclosure is shown. The channel region 201 includes a plurality of semiconductor layers 202 and a plurality of spacer layers 203, the semiconductor layers 202 are stacked and arranged at intervals, and the spacer layers 203 are respectively formed on opposite side walls of the semiconductor layers 202.

The present disclosure may be implemented in a semiconductor device 200 of nanosheet type, such as gate-all-around (GAA) devices, multi-bridge-channel (MBC) devices, a surrounding gate transistor (SGT) or other similar name. The semiconductor layer 202 may be one of many different shapes, such as a wire (or nanowire), a sheet (or nanosheet), a rod (or nanorod), and/or other suitable shapes.

The spacer layers 203 can serve as inner spacers. The spacer layers 203 are respectively formed between a source region and the semiconductor layers 202 and between a drain region and the semiconductor layers 202, in order to prevent electrical connection between the semiconductor layers 202 and the corresponding source region and the corresponding drain region, respectively.

As shown in FIG. 4, a trench 204 is formed to expose the sidewalls of the semiconductor layers 202. Next, precursor compounds formed by CVD or ALD and ring opening polymerization (see FIGS. 3A to 3E) are used to deposit the inner spacers (i.e., 203) on the sidewalls of the semiconductor layers 202, and then source/drain features on opposite sides of the channel region 201 are formed in the trench 204. In some embodiments, the source/drain features may be formed by epitaxial processes, such as vapor-phase epitaxy (VPE), ultra-high vacuum CVD (UHV-CVD), molecular beam epitaxy (MBE) and/or other suitable processes.

In some embodiments, hydroxide ions may be formed on the sidewalls of the semiconductor layers 202 prior to the step of forming precursor compounds by CVD or ALD. For example, the side walls of the semiconductor layers 202 are exposed to an oxygen-based plasma, a pre-soak process, or a combination thereof to perform a plasma treatment to the semiconductor layers 202. and make the degree of chemical adsorption on the sidewalls of the semiconductor layers 202 increasingly.

Referring to FIG. 5, a schematic diagram of a gate structure 300 according to another embodiment of the present disclosure is shown. The gate structure 300 includes a gate electrode layer 301, a gate dielectric layer 302 and a spacer wall 303. In some embodiments, precursor compounds formed by CVD or ALD and ring opening polymerization (see FIGS. 3A to 3E) are used to deposit the spacer wall 303 on the sidewalls of the gate structure 300, and then source/drain features on opposite sides of the gate structure 300 are formed in the trench 304.

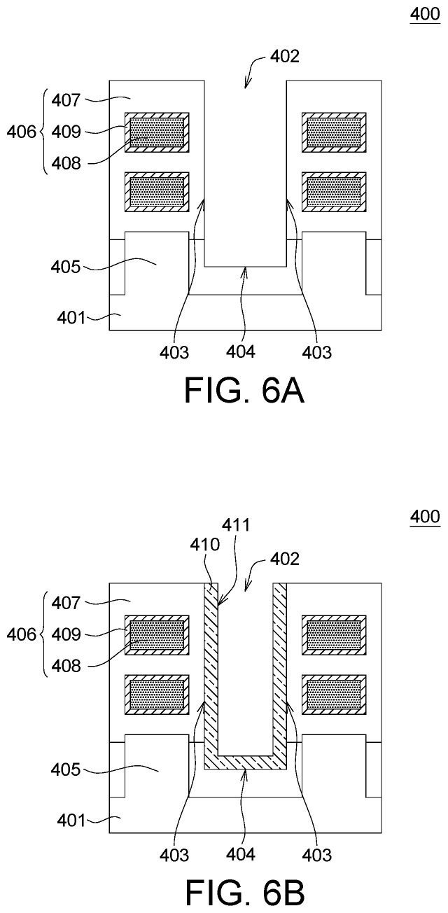

Referring to FIGS. 6A to 6B, schematic views of a method of manufacturing a semiconductor device according to an embodiment of the present disclosure are illustrated. In FIG. 6A, a semiconductor device 400 is formed. The semiconductor device 400 includes a substrate 401, at least one fin 405 and a gate structure 406 disposed on the fin 405. The gate structure 406 includes a gate electrode layer 407, a plurality of semiconductor layers 408 and a plurality of gate dielectric layers 409. The semiconductor layers 408 are disposed in the gate electrode layer 407, and the semiconductor layers 408 are stacked on each other and arranged at intervals. The gate dielectric layers 409 cover the semiconductor layers 408 and separate the gate electrode layer 407 from the semiconductor layers 408.

As shown in FIG. 6A, the gate electrode layer 407 is formed on the gate dielectric layer 409 and surrounds the gate dielectric layer 409. The gate electrode layer 407 may include a single layer or a multi-layer structure. The gate electrode layer 407 may include titanium nitride (TiN), titanium aluminum (TiAl), titanium aluminum nitride (TiAlN), tantalum nitride (TaN), Tantalum aluminum (TaAl), tantalum aluminum nitride (TaAlN), tantalum aluminum carbide (TaAlC), tantalum carbon nitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals or other suitable metal materials or combinations thereof. In addition, the gate dielectric layer 409 may include an interface layer (not shown) and a high-k gate dielectric layer. The interface layer is located on and surrounds the semiconductor layer 408, and the high-k gate dielectric layer is located on and surrounding the interface layer. In some embodiments, the interface layer includes silicon oxide. The gate dielectric layer 409 may include a high-k dielectric material, such as hafnium oxide. Alternatively, the gate dielectric layer 409 may also include other high-k dielectric materials, such as titanium oxide (TiO2), hafnium zirconium oxide (HfZrO), tantalum oxide (Ta2O5), hafnium silicon oxide (HfSiO4), zirconium oxide (ZrO2), zirconia silicon oxide (ZrSiO2), lanthanum oxide (La2O3), aluminum oxide (Al2O3), zirconium oxide (ZrO), yttrium oxide (Y2O3), SrTiO3(STO), BaTiO3(BTO), BaZrO, lanthanum hafnium oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO3(BST), silicon nitride (SiN), silicon oxynitride (SiON), combinations thereof or other suitable materials. The gate dielectric layer 409 may be formed by any suitable method, such as CVD, ALD, PVD, other suitable techniques, or a combination thereof. At this process stage, the gate dielectric layer 409 may surround four sides of the semiconductor layer 408, and the thickness of the gate dielectric layer 409 may be about 1.5 nm to about 3 nm.

In some embodiments, the gate structure 406 includes a trench 402 that exposes two opposite sidewalls 403 and a bottom surface 404 of the gate electrode layer 407. These trenches 402 are referred to as cut metal gate (CMG) trenches in this disclosure. As semiconductor devices continue to scale down, the aspect ratio of CMG trench 402 typically increases. The cut metal gate (CMG) processes are configured to form isolation structures that divide a continuous gate into segments across multiple active regions. Such isolation structures may be referred to as gate blocking features, blocking features, or cut metal gate (CMG) features.

Next, in FIG. 6B, precursor compounds formed by CVD or ALD and ring opening polymerization (see FIGS. 3A to 3E) are used to deposit a patterned dielectric layer 410 (such as a liner) to cover the gate structure 406. The patterned dielectric layer 410 has a recess portion 411 dented into the trench 402, and the depth of the recess portion 411 is greater than the width of the recess portion 411. In addition, the patterned dielectric layer 410 is disposed along the opposite sidewalls 403 of the gate electrode layer 407 and covers the bottom surface 404. The patterned dielectric layer 410 can serve as a CMG isolation structure.

The dielectric constant of the patterned dielectric layer 410 may be between 2 and 2.3, which is lower than the dielectric constant of the silicon oxide film formed by traditional oxidation treatment, so that it can effectively reduce the dielectric constant of the dielectric layer.

In the present disclosure, since the patterned dielectric layer 410 with strong Si—C—Si bonds and lower dielectric constant, it is not necessary to use a reactant gas for oxidizing the precursor, but use ring opening polymerization reaction for cycle-type precursor. In addition, the carbon atom content is increased in a low dielectric constant film (i.e., 114 and 116) due to strong Si—C—Si bonding so that a weight percentage of carbon atoms is greater than 15% (for example, about 20% to 30%), which can effectively reduce the dielectric constant of the film so as to improve the quality and performance of the semiconductor device 400.

The present disclosure is related to a semiconductor device with spacer layers formed by a precursor compound, a film deposited with the same and a method of manufacturing the film, which uses an atomic layer deposition (ALD) method to achieve a film deposition. The precursor compound contains a cyclic main chain of Si—C—Si bonds, and the cyclic main chains are ring-opened by UV light to form a plurality of non-cyclic monomers, and the non-cyclic monomers are polymerized to form a linear polymer. Since the linear polymer contains Si—C—Si bonds with strong and continuous bonding force, the bonding force of the film is increased accordingly.

According to some embodiments of the present disclosure, a semiconductor device including a gate structure having a channel region is provided. The channel region comprises a plurality of semiconductor layers and a plurality of spacer layers, wherein the semiconductor layers are stacked and arranged at intervals, and the spacer layers are respectively formed on opposite side walls of the semiconductor layers, wherein the spacer layers is made from a precursor compound, represented by the following chemical formula 1, wherein the precursor compound contains a cyclic main chain of Si—C—Si bonds, and the cyclic main chains are ring-opened by UV light to form a plurality of non-cyclic monomers, and the non-cyclic monomers are polymerized to form a linear polymer. In chemical formula 1, R1 is a functional group containing silicon, and R2 is a functional group containing carbon.

According to some embodiments of the present disclosure, a method of manufacturing a film is provided, which includes the following steps: Step 110, a plurality of precursor compounds is physically/chemically adsorbed on a substrate by an atomic layer deposition (ALD), each of the precursor compounds contains a Si—C—Si bond in a cyclic main chain; step 120, a gas is used to purge unadsorbed precursor compounds and a first pulsed UV light irradiates on the precursor compounds to break one Si—C bond of the Si—C—Si bond in the cyclic main chain; Step 130, a second pulsed UV light or plasma is used to connect a functional group R1 on one branch chain of one broken Si—C bond with a functional group R2 on one branch chain of another broken Si—C bond to form a first film layer.

According to some embodiments of the present disclosure, a film is provided, which is deposited using the above-mentioned manufacturing method to obtain the first film layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1-4. (canceled)

5. A method of manufacturing a film, comprising:
physically/chemically adsorbing a plurality of precursor compounds on a substrate by an atomic layer deposition (ALD), each of the precursor compounds contains a Si—C—Si bond in a cyclic main chain;
purging unadsorbed precursor compounds with a gas and irradiating a first pulsed UV light to break one Si—C bond of the Si—C—Si bond in each of the cyclic main chains; and
using a second pulsed UV light or plasma to connect a functional group R1 on one branch chain of one broken Si—C bond with a functional group R2 on one branch chain of another broken Si—C bond to form a first film layer.

6. The method of manufacturing a film according to claim 5, wherein the functional group R1 contains silicon, and the functional group R2 contains carbon.

7. The method of manufacturing a film according to claim 5, wherein the functional group R1 is cross-linked to the functional group R2 to generate another functional group R3 and release by-products, wherein the functional group R3 contains a Si—C bond.

8. The method of manufacturing a film according to claim 5, wherein the cyclic main chains of the precursor compounds form a plurality of non-cyclic monomers through ring opening.

9. The method of manufacturing a film according to claim 8, wherein the non-cyclic monomers form a linear polymer through a polymerization reaction.

10. The method of manufacturing a film according to claim 5, wherein after forming the first film layer, the method further comprises:
physically/chemically adsorbing another plurality of precursor compounds on the first film layer by an atomic layer deposition (ALD), and each of the precursor compounds contains Si—C—Si bonds in a cyclic main chain;
purging unadsorbed precursor compounds with a gas and irradiating the first pulsed UV light to break one Si—C bond of the Si—C—Si bond in each of the cyclic main chains;
using the second pulsed UV light or plasma to connect the functional group R1 on one branch chain of one broken Si—C bond with the functional group R2 on one branch chain of another broken Si—C bond to form a second film layer.

11. The method of manufacturing a film according to claim 10, wherein the cyclic main chains of the precursor compounds form a plurality of non-cyclic monomers through ring opening.

12. The method of manufacturing a film according to claim 11, wherein the non-cyclic monomers form a linear polymer through a polymerization reaction.

13. The method of manufacturing a film according to claim 10, wherein the first film layer and the second film layer are cross-linked with a functional group R1 on one branch chain of one Si—C bond and a functional groups R2 on one branch chain of another Si—C bond.

14. The method of manufacturing a film according to claim 13, wherein the functional group R1 is cross-linked to the functional group R2 to generate another functional group R3 and release by-products, wherein the functional group R3 contains a Si—C bond.

15. The method of manufacturing a film according to claim 13, wherein the functional group R1 contains silicon, and the functional group R2 contains carbon.

16-20. (canceled)

21. A method of manufacturing a film, comprising:
physically/chemically adsorbing a plurality of precursor compounds on a substrate by an atomic layer deposition (ALD), each of the precursor compounds contains a Si—C—Si bond in a cyclic main chain;
purging unadsorbed precursor compounds with a gas and irradiating a first pulsed UV light to break one Si—C bond of the Si—C—Si bond in each of the cyclic main chains; and
using a second pulsed UV light or plasma to connect a functional group R1 on one branch chain of one broken Si—C bond with a functional group R2 on one branch chain of another broken Si—C bond to form a first film layer, wherein the functional group R1 is cross-linked to the functional group R2 to generate another functional group R3 and release by-products, wherein the functional group R3 contains a Si—C bond,
wherein the first film layer is represented by chemical formula 1,

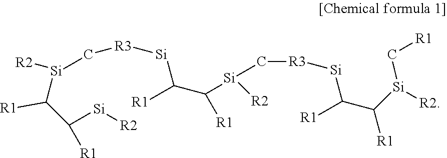

22. The method according to claim 21, wherein the functional group R1 is a silyl group.

23. The method according to claim 21, wherein the functional group R2 is a chloromethyl group.

24. The method according to claim 21, wherein the functional group R1 contains silicon, and the functional group R2 contains carbon.

25. A method of manufacturing a film, comprising:
providing a plurality of precursor compounds, each of the precursor compounds contains a Si—C—Si bond in a cyclic main chain;
breaking one Si—C bond of the Si—C—Si bond in each of the cyclic main chains to form a plurality of non-cyclic monomers;
connecting the non-cyclic monomers to form a linear polymer through a polymerization reaction, wherein a functional group R1 on one branch chain of one broken Si—C bond is cross-linked to a functional group R2 on one branch chain of another broken Si—C bond to generate another functional group R3 and release by-products,
wherein the linear polymer is represented by chemical formula 1,

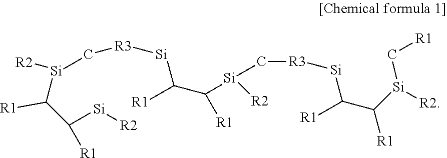

26. The method according to claim 25, wherein the functional group R1 is a silyl group.

27. The method according to claim 25, wherein the functional group R2 is a chloromethyl group.

28. The method according to claim 25, wherein the functional group R1 contains silicon, and the functional group R2 contains carbon.

29. The method according to claim 25, wherein the functional group R3 contains a Si—C bond.
